(19) United States
(12) Patent Application Publication
(10) Pub. No.: US 2017/0286219 A1
(43) Pub. Date: Oct. 5, 2017

(54) DATA STORAGE DEVICE AND OPERATING METHOD THEREOF

(71) Applicant: SK hynix Inc., Gyeonggi-do (KR)

(72) Inventor: Chol Su CHAE, Gyeonggi-do (KR)

(21) Appl. No.: 15/230,172

(22) Filed: Aug. 5, 2016

(30) Foreign Application Priority Data
Apr. 4, 2016 (KR) 10-2016-0041241

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

A method for operating a data storage device includes reading out a data chunk from a nonvolatile memory device; arranging first codes and second codes of the read-out data chunk in the form of a matrix; and determining the total number of corrected error bits for the data chunk by decoding the respective first codes and the respective second codes, and summing the numbers of corrected error bits of the respective decoded first codes and the respective decoded second codes.

### CROSS-REFERENCES TO RELATED APPLICATION

The present application claims priority under 35 U.S.C. §119(a) to Korean application number 10-2016-0041241, filed on Apr. 4, 2016, in the Korean Intellectual Property Office, which is incorporated herein by reference in its entirety.

### BACKGROUND

### 1. Technical Field

Various embodiments generally relate to a semiconductor device, and, more particularly, to a data storage device and an operating method thereof.

### 2. Related Art

Recently, the paradigm for the computer environment has been converted into ubiquitous computing so that computer systems can be used anytime and anywhere. Due to this fact, the use of portable electronic devices such as mobile phones, digital cameras, and notebook computers has rapidly increased. In general, such portable electronic devices use a data storage device which uses a memory device. The data storage device is used as an auxiliary memory device of the portable electronic devices.

A data storage device using a memory device provides advantages in that, since there is no mechanical driving part, stability and durability are excellent, an information access speed is high and power consumption is small. Data storage devices having such advantages include a universal serial bus (USB) memory device, memory cards having various interfaces, and a solid state drive (SSD).

As portable electronic devices are expected to be capable of running a large file, such as a music file or a video file, a data storage device used in such portable electronic devices should also have a large storage capacity. A data storage device uses, as a storage medium, a memory device having a high integration degree of memory cells to secure a large storage capacity. A flash memory device is an example of a widely used nonvolatile memory device having a high integration degree.

### SUMMARY

Various embodiments are directed to a data storage device and an operating method thereof, capable of estimating the number of error bits in data read out from a nonvolatile memory device.

Also, various embodiments are directed to a data storage device and an operating method thereof, capable of determining a state of memory cells in which data are stored, based on the estimated number of error bits.

In an embodiment, a method for operating a data storage device may include: reading out a data chunk from a nonvolatile memory device; arranging first codes and second codes of the read-out data chunk in the form of a matrix; and determining the total number of corrected error bits for the data chunk by decoding the respective first codes and the respective second codes, and summing the numbers of corrected error bits of the respective decoded first codes and the respective decoded second codes.

In an embodiment, a data storage device may include: a nonvolatile memory device in which a data chunk is stored; a control unit suitable for reading out the data chunk from the nonvolatile memory device; and an error correction code (ECC) unit suitable for arranging first codes and second codes of the read-out data chunk in the form of a matrix, and determining the total number of corrected error bits for the data chunk by performing a decoding operation for the respective first codes and the respective second codes, and counting and summing the numbers of corrected error bits of the respective decoded first codes and the respective decoded second codes.

According to the embodiments, since a separate memory space for storing a read-out data chunk is not needed, it is possible to substantially prevent the size of an error correction code (ECC) logic from increasing.

Moreover, since the number of erroneously corrected error bits is subtracted from the total number of accumulated error bits, the number of error bits in a read-out data chunk may be precisely estimated. As a consequence, a state of memory cells in which the corresponding data chunk is stored may be precisely determined.

### BRIEF DESCRIPTION OF THE DRAWINGS

The above and other features and advantages of the present invention will become more apparent to those skilled in the art to which the present invention belongs by describing in detail various embodiments thereof with reference to the attached drawings in which:

FIG. 1 is a block diagram illustrating a data storage device in accordance with an embodiment of the present invention.

FIG. 2 is a diagram illustrating an example of a data chunk DCK including codes which are arranged in the form of a matrix by an error correction code (ECC) unit.

FIG. 3 is a diagram illustrating an example of a data chunk DCK including 4 row codes and 4 column codes each of which includes data blocks each having 4-bit data.

FIGS. 4A and 4B are diagrams illustrating an example of a case where there is no erroneously corrected bit in the process of performing a decoding operation for the data chunk DCK.

FIGS. 5A and 5B are diagrams illustrating an example of a case where there are erroneously corrected bits in the process of performing a decoding operation for the data chunk DCK.

FIG. 6 is a flow chart illustrating a method for operating a data storage device in accordance with an embodiment of the present invention.

FIG. 7 is a flow chart illustrating step S300 shown in FIG. 6 in more detail.

FIG. 8 is a flow chart illustrating step S400 shown in FIG. 6 in more detail.

FIG. 9 is a block diagram illustrating a data processing system including a data storage device in accordance with an embodiment of the present invention.

FIG. 10 is a block diagram illustrating a data processing system including a solid state drive (SSD) in accordance with an embodiment of the present invention.

FIG. 11 is a block diagram illustrating a solid state drive (SSD) controller of FIG. 10.

FIG. 12 is a block diagram illustrating a computer system to which a data storage device is mounted in accordance with the embodiment of the present invention.

FIG. 13 is a block diagram illustrating a nonvolatile memory device included in a data storage device in accordance with an embodiment of the present invention.

### DETAILED DESCRIPTION

Hereinafter, a data storage device and an operating method thereof will be described below with reference to the accompanying drawings through various examples of embodiments.

The present disclosure, however, may be embodied in various different forms, and should not be construed as being limited to the illustrated embodiments herein. Rather, these embodiments are provided as examples so that this disclosure will be thorough and complete, and will fully convey the various aspects and features of the present invention to those skilled in the art.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to more clearly illustrate the various elements of the embodiments. For example, in the drawings, the size of elements and the intervals between elements may be exaggerated compared to actual sizes and intervals for convenience of illustration.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises”, “comprising”, “includes”, and “including” when used in this specification, specify the presence of the stated elements and do not preclude the presence or addition of one or more other elements. As used herein, the term “and/or” includes any and all combinations of one or more of the associated listed items.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described in detail with reference to the attached drawings. Throughout the various drawings like numbers denote like elements.

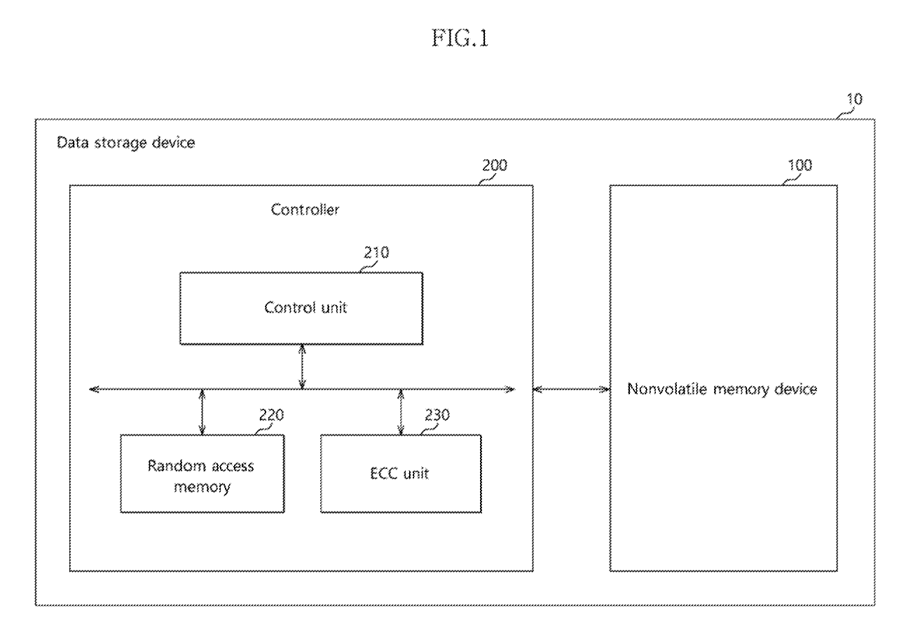

Referring now to FIG. 1, a data storage device 10 is provided in accordance with an embodiment of the present invention.

The data storage device 10 may store data to be accessed by a host device (not shown) such as a mobile phone, an MP3 player, a laptop computer, a desktop computer, a game player, a television (TV), an in-vehicle infotainment system, and so forth. The data storage device 10 may be referred to as a memory system. The data storage device 10 may be coupled to the host via a suitable communication link. The communication link may be a wireless communication link.

The data storage device 10 may be manufactured as any one of various kinds of storage devices according to the protocol of an interface which is electrically coupled with the host device. For example, the data storage device 10 may be configured as any one of various kinds of storage devices such as a solid state drive (SSD), a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, a memory stick, and so forth.

The data storage device 10 may be manufactured as any one among various kinds of package types. For example, the data storage device 10 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The data storage device 10 may include a nonvolatile memory device 100 and a controller 200.

The nonvolatile memory device 100 may operate as the storage medium of the data storage device 10. The nonvolatile memory device 100 may be configured by any one of various types of nonvolatile memory devices such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PCRAM) using a chalcogenide alloy, and a resistive random access memory (RERAM) using a transition metal compound, according to memory cells.

The controller 200 may include a control unit 210, a random access memory 220, and an error correction code (ECC) unit 230.

The control unit 210 may control general operations of the controller 200. The control unit 210 may analyze and process a signal, a command or a request which is inputted from the host device. For example, when a read request and a logical address to read are received from the host device, the control unit 210 may read out data from the nonvolatile memory device 100 based on the received logical address. Also, when a write request and a logical address to write are received from the host device, the control unit 210 may store data in the nonvolatile memory device 100 based on the received logical address. For example, to accomplish these functions, the control unit 210 may decode and drive a firmware (or a software) loaded in the random access memory 220. The control unit 210 may be realized in the form of a hardware or in the combined form of a hardware and a software.

The random access memory 220 may store the firmware (or the software) which is to be driven by the control unit 210. Also, the random access memory 220 may store data necessary for the driving of the firmware (or the software) (e.g., metadata). That is to say, the random access memory 220 may operate as the working memory of the control unit 210.

The random access memory 220 may temporarily store data to be transmitted from the host device to the nonvolatile memory device 100 or data to be transmitted from the nonvolatile memory device 100 to the host device. In other words, the random access memory 220 may operate as a data buffer memory or a data cache memory.

The ECC unit 230 may ECC-decode (hereinafter, simply referred to as ‘decode’) the data read out from the nonvolatile memory device 100. In detail, the ECC unit 230 may detect and correct error bits in the data read out from the nonvolatile memory device 100, by using parity bits generated during an encoding process. When the number of error bits in read-out data is equal to or less than a predetermined number, the ECC unit 230 may correct detected error bits. When the number of error bits in read-out data exceeds the predetermined number, the ECC unit 230 may not correct detected error bits. The predetermined number may mean the error correction capability of the ECC unit 230.

After performing a decoding operation for the data read out from the nonvolatile memory device 100, the ECC unit 230 may perform a syndrome check for decoded data and generate a decoding result value. The decoding result value may be a value that indicates a decoding success or a decoding failure. The decoding success may mean that a correction-failed error bit does not exist in the decoded data, and the decoding failure may mean that a correction-failed error bit exists in the decoded data.

The ECC unit 230 may perform error correction by using, but not limited to, one of a low density parity check (LDPC) code, a Bose-Chaudhuri-Hocquenghem (BCH) code, a turbo code, a Reed-Solomon code, a convolution code, a recursive systematic code (RSC), and coded modulation such as trellis-coded modulation (TCM) and block-coded modulation (BCM). The ECC unit 230 may include a circuit, system or device for error correction.

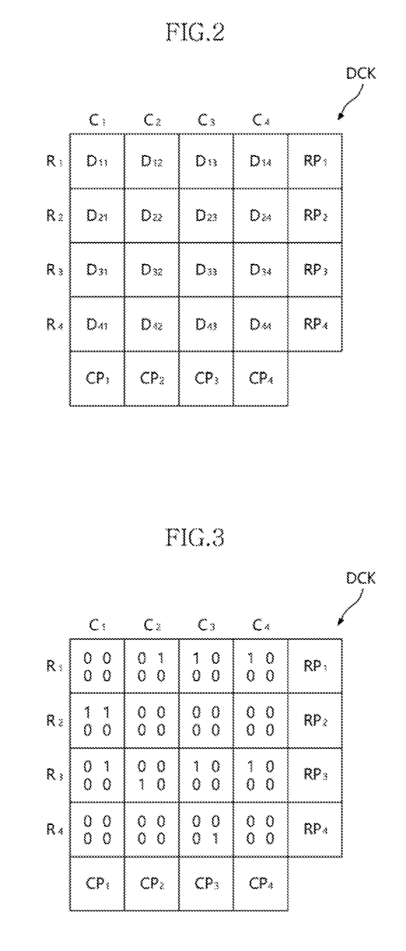

FIG. 2 is a diagram illustrating a data chunk DCK including codes which are arranged in the form of a matrix by the ECC unit 230 of FIG. 1.

Referring to FIG. 2, the ECC unit 230 may arrange a data chunk DCK read out from the nonvolatile memory device 100, in the form of a matrix. The data chunk DCK may include a plurality of row codes and a plurality of column codes which are arranged in the form of a matrix by the ECC unit 230. Each of the plurality of row codes and the plurality of column codes may include a plurality of data blocks and one parity block. For example, as shown in FIG. 2, in the case where the data chunk DCK includes 4 row codes R₁ to R₄ and 4 column codes C₁ to C₄, the data chunk DCK may include 16 data blocks D₁₁ to D₄₄, 4 row parity blocks RP₁ to RP₄, and 4 column parity blocks CP₁ to CP₄. Each of the data blocks D₁₁ to D₄₄ may include data of 1 or more bits.

The ECC unit 230 may decode, by the unit of code, the row codes R₁ to R₄ and the column codes C₁ to C₄. In an embodiment, the ECC unit 230 may sequentially decode the row codes R₁ to R₄ and may then sequentially decode the column codes C₁ to C₄. In another embodiment, the ECC unit 230 may sequentially decode the column codes C₁ to C₄ and may then sequentially decode the row codes R₁ to R₄. In yet another embodiment, the ECC unit 230 may decode the row and column codes in an alternating way, for example, starting with decoding a first row code first followed by a first column code, followed by a second row code, and so on and so forth.

The ECC unit 230 may count and sum the numbers of error bits detected and corrected in the process of performing a decoding operation for the row codes R₁ to R₄ and the column codes C₁ to C₄, and calculate the total number of corrected error bits for the decoded data chunk DCK.

For example, in reference to FIG. 2, the ECC unit 230 may detect and correct error bits included in the data blocks D₁₁ to D₁₄ of the first row code R₁, and count the number of corrected error bits. Then, the ECC unit 230 may detect and correct error bits included in the data blocks D₂₁ to D₂₄ of the second row code R₂, count the number of corrected error bits, and sum the number of corrected error bits with the number of corrected error bits that is counted by decoding the first row code R₁. Thereafter, the ECC unit 230 may detect and correct error bits included in the third row code R₃, the fourth row code R₄, the first column code C₁, the second column code C₂, the third column code C₃ and the fourth column code C₄, count the numbers of corrected error bits, sum the numbers of corrected error bits with the numbers of corrected error bits of previously decoded codes (that is, the first row code R₁ and the second row code R₂), and calculate the total number of corrected error bits corrected while decoding one data chunk DCK.

If detection and correction of error bits is normally performed in the process of decoding the row codes R₁ to R₄ and the column codes C₁ to C₄ of the data chunk DCK, the number of error bits in the data chunk DCK read out from the nonvolatile memory device 100 and the number of corrected error bits in the decoded data chunk DCK may be the same with each other. In this case, the number of error bits in the data chunk DCK read out from the nonvolatile memory device 100 may be estimated based on the numbers of corrected error bits counted and summed while performing the decoding operation.

Meanwhile, as aforementioned above, in the case where the number of error bits detected in each of row codes or column codes is out of a predetermined error correction capability range, the ECC unit 230 may not correct error bits.

However, even though the number of error bits is out of the predetermined error correction capability range, there may be a case where the number of error bits is erroneously determined as being within the predetermined error correction capability range and bits determined as error bits are corrected. That is to say, an erroneous correction may occur in the decoding process. Moreover, even when an erroneous correction occurs, a decoding result value indicating a decoding success may be generated.

In this case, the number of error bits in the data chunk DCK read out from the nonvolatile memory device 100 and the number of corrected error bits in the decoded data chunk DCK may be different from each other. In other words, due to an erroneous correction, the number of corrected error bits may be greater than the number of error bits actually included in the data chunk DCK. As a result, it may be difficult to precisely estimate the number of error bits in the data chunk DCK read out from the nonvolatile memory device 100.

If an error bit is detected in a row code (or a column code) for which a decoding operation is being currently performed, the ECC unit 230 may check the decoding result value of a column code (or a row code) which shares a data block where the error bit is detected. If a checking result is a decoding success, the ECC unit 230 may subtract the number of corrected error bits that is counted while decoding the corresponding column code (or the corresponding row code), from the total number of corrected error bits. In addition, the ECC unit 230 may change the decoding result value of the corresponding column code (or the corresponding row code), to a value corresponding to a decoding failure. In this regard, because erroneously corrected error bits are counted again as the number of corrected error bits while being corrected in the decoding process subsequently performed, the number of error bits actually included in the data chunk DCK may be precisely estimated by subtracting two times the number of erroneously corrected error bits from the total number of corrected error bits.

The control unit 210 may determine whether the total number of corrected error bits for the data chunk DCK, estimated by the ECC unit 230, is less than or equal to or greater than a predetermined threshold number of error bits, and, based on a determination result, may determine the state of memory cells of the nonvolatile memory device 100 in which the data chunk DCK is stored.

In detail, if the total number of corrected error bits is less than the predetermined threshold number of error bits, the control unit 210 may determine that the state of the memory cells in which the data chunk DCK is stored is good, and may end the operation. However, if the total number of corrected error bits is equal to or greater than the predetermined threshold number of error bits, the control unit 210 may determine that the state of the memory cells in which the data chunk DCK is stored is bad, and may store the data chunk DCK in other memory cells excluding the current memory cells.

FIG. 3 is a diagram illustrating a data chunk DCK including row codes and column codes each of which includes data blocks each having 4-bit data. As an example, it is assumed that a decoding operation for column codes is started after a decoding operation for row codes is completed. Also, it is assumed that ‘0’ is a normal bit and ‘1’ is an error bit, and it is assumed that the error correction capability of the ECC unit 230 is 3 bits.

Referring to FIG. 3, a first row code R₁ may include 3 error bits, a second row code R₂ may include 2 error bits, a third row code R₃ may include 4 error bits, and a fourth row code R₄ may include 1 error bit.

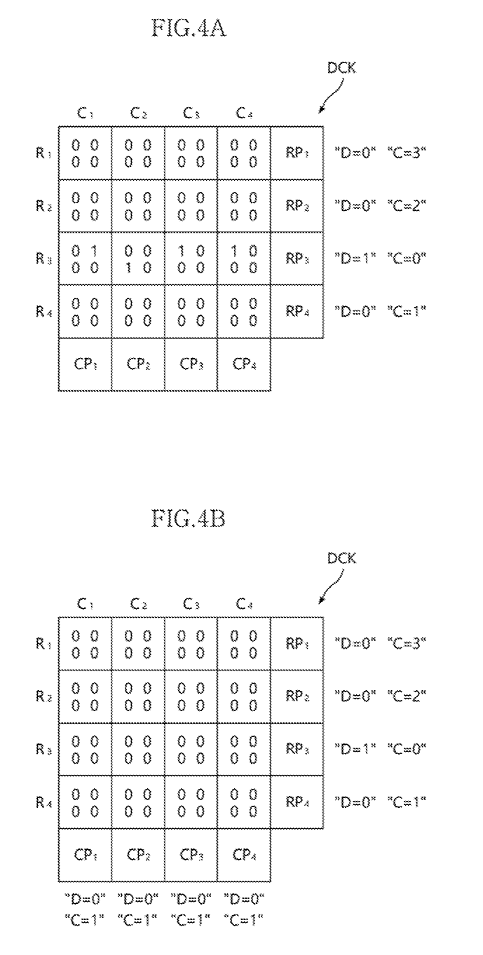

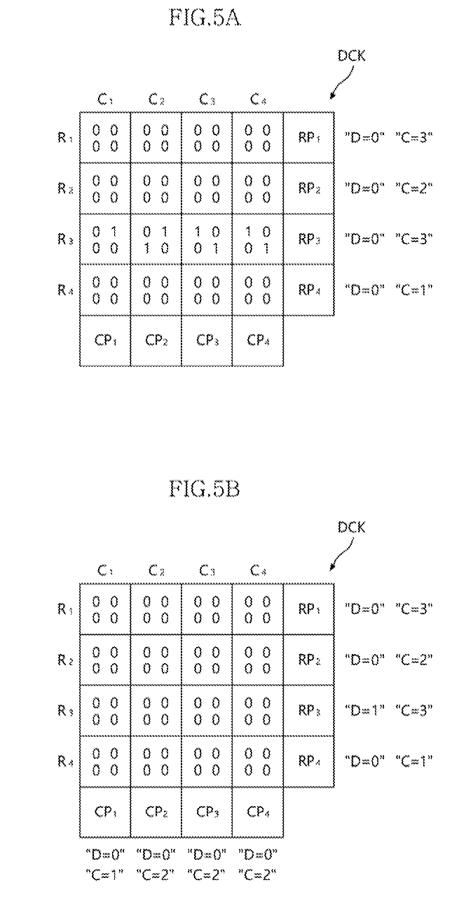

FIGS. 4A and 4B are a representation of an example of a case where there is no erroneously corrected bit in the process of performing a decoding operation for the data chunk DCK.

Referring to FIG. 4A, the ECC unit 230 may perform the decoding operation for the first row code R₁, based on a first row parity block RP₁, and detect and correct the error bits of the first row code R₁. The ECC unit 230 may perform a syndrome check for the decoded first row code R₁, generate a decoding result value D=0 indicating a decoding success, and count the number of corrected error bits C=3.

Thereafter, the ECC unit 230 may perform the decoding operation for the second row code R₂, based on a second row parity block RP₂, and detect and correct the error bits of the second row code R₂. The ECC unit 230 may perform the syndrome check for the decoded second row code R₂, generate a decoding result value D=0 indicating a decoding success, and count the number of corrected error bits C=2. The ECC unit 230 may sum the number of corrected error bits C=2 of the second row code R₂ and the number of corrected error bits C=3 of the first row code R₁, and calculate the total number of corrected error bits. Accordingly, after performing the decoding operation up to the second row code R₂, the total number of corrected error bits becomes 5.

Thereafter, the ECC unit 230 may perform the decoding operation for the third row code R₃, based on a third row parity block RP₃, and detect the error bits of the third row code R₃. The detected error bits are 4 bits, and exceed the error correction capability, as 3 bits, of the ECC unit 230. Therefore, the ECC unit 230 may not correct the detected error bits. The ECC unit 230 may perform the syndrome check for the decoded third row code R₃, and generate a decoding result value D=1 indicating a decoding failure. Since the detected error bits are not corrected, the number of corrected error bits is 0, that is, C=0. Accordingly, after performing the decoding operation up to the third row code R₃, the total number of corrected error bits is still 5.

Thereafter, the ECC unit 230 may perform the decoding operation for the fourth row code R₄, based on a fourth row parity block RP₄, and detect and correct the error bit of the fourth row code R₄. The ECC unit 230 may perform the syndrome check for the decoded fourth row code R₄, generate a decoding result value D=0 indicating a decoding success, and count the number of corrected error bits C=1. The ECC unit 230 may sum the number of corrected error bits C=1 of the fourth row code R₄ with the total number of corrected error bits of 5 that is acquired by summing the number of corrected error bits C=3 of the previously decoded first row code R₁ and the number of corrected error bits C=2 of the previously decoded second row code R₂. Accordingly, after the decoding operation for the first to fourth row codes R₁ to R₄ is completed, the total number of corrected error bits becomes 6.

Next, referring to FIG. 4B, the ECC unit 230 may perform the decoding operation for the first to fourth column codes C₁ to C₄, based on first to fourth column parity blocks CP₁ to CP₄, and detect and correct the error bits of the first to fourth column codes C₁ to C₄. The ECC unit 230 may perform the syndrome check for the respective decoded first to fourth column codes C₁ to C₄, and generate decoding result values D=0, D=0, D=0 and D=0 indicating decoding successes. The ECC unit 230 may count the numbers of corrected error bits of the first to fourth column codes C₁ to C₄ as C=1, C=1, C=1 and C=1. The ECC unit 230 may sum the respective numbers of corrected error bits C=1, C=1, C=1 and C=1 of the first to fourth column codes C₁ to C₄, sequentially with the total number of corrected error bits.

As a result, the total number of corrected error bits corrected while decoding the data chunk DCK is 10, and is the same as the number of error bits actually included in the data chunk DCK read out from the nonvolatile memory device 100 as shown in FIG. 3.

In this way, by counting and accumulating in real time the numbers of error bits corrected in the process of performing the decoding operation for the row codes R₁ to R₄ and the column codes C₁ to C₄ of the data chunk DCK, it is possible to estimate the number of error bits in the data chunk DCK read out from the nonvolatile memory device 100. Because it is not necessary to compare the read-out data chunk DCK and the decoded data chunk DCK, a memory space for separately storing the read-out data chunk DCK is not needed.

FIGS. 5A and 5B illustrate an example where there are erroneously corrected bits in the process of performing a decoding operation for the data chunk DCK.

Referring to FIGS. 3 and 5A, the ECC unit 230 may perform the decoding operation for the first row code R₁, based on a first row parity block RP₁, and detect and correct the error bits of the first row code R₁. The ECC unit 230 may perform a syndrome check for the decoded first row code R₁, generate a decoding result value D=0 indicating a decoding success, and count the number of corrected error bits C=3. Thereafter, the ECC unit 230 may perform the decoding operation for the second row code R₂, based on a second row parity block RP₂, and detect and correct the error bits of the second row code R₂. The ECC unit 230 may perform the syndrome check for the decoded second row code R₂, generate a decoding result value D=0 indicating a decoding success, and count the number of corrected error bits C=2. The ECC unit 230 may sum the number of corrected error bits C=2 of the second row code R₂ and the number of corrected error bits C=3 of the first row code R₁, and calculate the total number of corrected error bits. Accordingly, after performing the decoding operation up to the second row code R₂, the total number of corrected error bits becomes 5.

Thereafter, the ECC unit 230 may perform the decoding operation for the third row code R₃, based on a third row parity block RP₃, and detect the error bits of the third row code R₃. The detected error bits are 4 bits, and exceed the error correction capability, as 3 bits, of the ECC unit 230. However, the ECC unit 230 may erroneously determine that the detected error bits are within the error correction capability, erroneously detect the positions of error bits and determine normal bits as error bits, and correct the normal bits which are determined as error bits. The ECC unit 230 may perform the syndrome check for the decoded third row code R₃, erroneously calculate that decoding has succeeded and generate a decoding result value D=0 indicating a decoding success, and count the number of corrected error bits C=3. The ECC unit 230 may sum the number of corrected error bits C=3 of the third row code R₃ with the total number of corrected error bits of 5 that is acquired by summing the number of corrected error bits C=3 of the previously decoded first row code R₁ and the number of corrected error bits C=2 of the previously decoded second row code R₂. Accordingly, after the decoding operation for the third row code R₃ is completed, the total number of corrected error bits becomes 8.

Since the error bits originally included in the third code R₃ are not corrected and the normal 3 bits are erroneously corrected, 7 error bits exist in the decoded third row code R₃.

Thereafter, the ECC unit 230 may perform the decoding operation for the fourth row code R₄, based on a fourth row parity block RP₄, and detect and correct the error bit of the fourth row code R₄. The ECC unit 230 may perform the syndrome check for the decoded fourth row code R₄, generate a decoding result value D=0 indicating a decoding success, and count the number of corrected error bits C=1. The ECC unit 230 may sum the number of corrected error bits C=1 of the fourth row code R₄ with the total number of corrected error bits of 8 that is acquired by summing the number of corrected error bits C=3 of the previously decoded first row code R₁, the number of corrected error bits C=2 of the previously decoded second row code R₂ and the number of corrected error bits C=3 of the previously decoded third row code R₃. Accordingly, after the decoding operation for the first to fourth row codes R₁ to R₄ is completed, the total number of corrected error bits becomes 9.

Since all the decoding result values of the first to fourth row codes R₁ to R₄ are ‘0,’ no error bit should exist in the first to fourth column codes C₁ to C₄ when subsequently performing the decoding operation for the first to fourth column codes C₁ to C₄. However, in the case where an erroneous correction has occurred as described above, even though all the decoding result values are ‘0,’ error bits may be detected in the first to fourth column codes C₁ to C₄.

That is to say, referring to FIG. 5A, the ECC unit 230 may perform the decoding operation for the first column code C₁, based on a first column parity block CP₁, and detect the error bit of the first column code C₁. The ECC unit 230 may check the decoding result value of the third row code R₃ which shares a data block D₃₁ where the detected error bit is included, and determine, based on the decoding result value of the third row code R₃, that the corrected error bits of the third row code R₃ have been erroneously corrected.

Therefore, as shown in FIG. 5B, the ECC unit 230 may change the decoding result value for the third row code R₃ from ‘0’ to ‘1.’ Moreover, the ECC unit 230 may subtract the number of corrected error bits C=3 of the third row code R₃ from the total number of corrected error bits. In this regard, the corrected error bits of the third row code R₃ may be not the error bits originally included in the data chunk DCK read out from the nonvolatile memory device 100. Nevertheless, these error bits are corrected while performing the decoding operation for the first to fourth column codes C₁ to C₄, and are counted again as the number of corrected error bits. As a consequence, the number of corrected error bits of the decoded data chunk DCK may be still greater than the actual number of error bits of the data chunk DCK. Hence, the ECC unit 230 may subtract 6 bits as two times the number of corrected error bits C=3 of the third row code R₃ from the total number of corrected error bits of 9. As a result, the total number of corrected error bits becomes 3.

While it was described in the present embodiment that two times the number of erroneously corrected error bits is subtracted from the total number of corrected error bits, it is to be noted that the embodiment is not specifically limited to such. For estimating the number of error bits of the data chunk DCK read out from the nonvolatile memory device 100, a value obtained by multiplying or adding a constant for improving precision to the number of erroneously corrected error bits may be subtracted from the total number of corrected error bits. This allows for a more precise estimate of the error bits of the data chunk DCK read out from the nonvolatile memory device 100.

The ECC unit 230 may correct the error bit detected in the first column code C₁, perform the syndrome check for the decoded first column code C₁, generate a decoding result value D=0 indicating a decoding success, and count the number of corrected error bits C=1. The ECC unit 230 may sum the number of corrected error bits C=1 of the first column code C₁ with the total number of corrected error bits of 3 that is acquired by subtracting the number of erroneously corrected error bits from the total number of corrected error bits. As a result, the total number of corrected error bits becomes 4.

Thereafter, the ECC unit 230 may detect and correct error bits by performing the decoding operation for the second to fourth column codes C₂ to C₄ based on second to fourth column parity blocks CP₂ to CP₄, perform the syndrome check for the decoded second to fourth column codes C₂ to C₄, generate decoding result values D=0, D=0 and D=0 indicating decoding successes, and count the numbers of corrected error bits C=2, C=2 and C=2. The ECC unit 230 may sum the respective numbers of corrected error bits C=2, C=2 and C=2 of the second to fourth column codes C₂ to C₄, sequentially with the total number of corrected error bits of 4. As a result, the total number of corrected error bits becomes 10.

In other words, the total number of corrected error bits corrected while decoding the data chunk DCK is 10, and is the same as the number of error bits in the data chunk DCK read out from the nonvolatile memory device 100 as shown in FIG. 3.

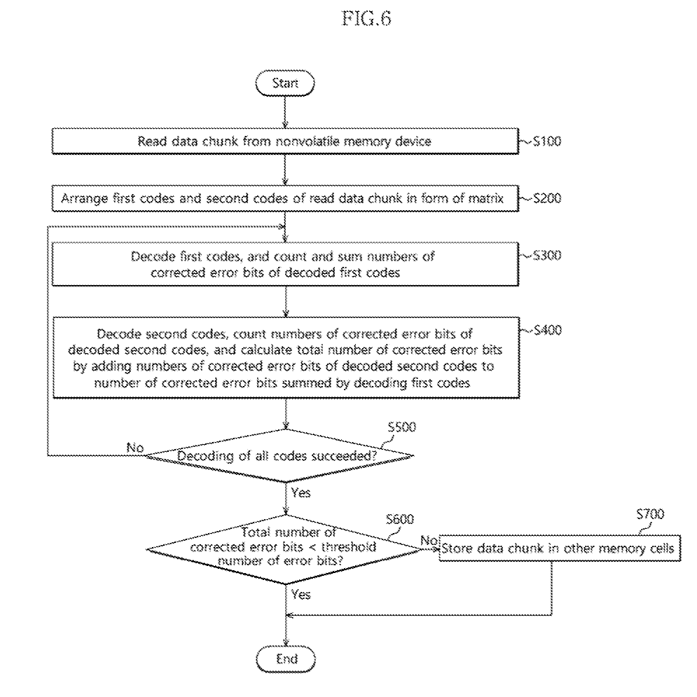

FIG. 6 is a flow chart illustrating a method for operating a data storage device in accordance with an embodiment of the present invention. In describing the flow chart of FIG. 6, reference may be made to FIGS. 1 to 5B. In FIG. 6, first codes may mean row codes, and second codes may mean column codes. However, it is to be noted that the embodiment is not specifically limited to such. Thus, first codes may mean column codes, and second codes may mean row codes. While FIG. 6 shows that second codes are decoded after decoding for first codes is completed, it is to be noted that the embodiment is not specifically limited to such. Thus, as a matter of course, FIG. 6 may be applied to an embodiment in which first codes and second codes are alternately decoded. In the present embodiment, it is assumed that first codes are row codes, second codes are column codes and the second codes are decoded after decoding for the first codes is completed.

Referring to FIG. 6, when a read request is received from the host device, the controller 200 of FIG. 1 may read out the data chunk DCK from the nonvolatile memory device 100 (S100). Thereafter, as shown in FIG. 2, the ECC unit 230 may arrange the first codes and the second codes of the read-out data chunk DCK, in the form of a matrix (S200).

The ECC unit 230 may decode the respective first to fourth row codes R₁ to R₄, and count and sum the respective numbers of corrected error bits of the decoded first to fourth row codes R₁ to R₄ (S300). Then, the ECC unit 230 may decode the respective first to fourth column codes C₁ to C₄, count the respective numbers of corrected error bits of the decoded first to fourth column codes C₁ to C₄, sum (or add) the respective numbers of corrected error bits to the numbers of corrected error bits summed while decoding the first to fourth row codes R₁ to R₄, and thereby calculate the total number of corrected error bits (S400) based on the summing result.

Thereafter, the ECC unit 230 may determine whether decoding results for all of the row codes R₁ to R₄ and the column codes C₁ to C₄ are successes (S500). As a result of the determination, if a code of which decoding result is a failure exists (S500, No), the process may proceed to the step S300 and the step S300 may be performed. The steps S300 to S500 may be iterated until decoding results for all of the row codes R₁ to R₄ and the column codes C₁ to C₄ are successes.

Meanwhile, as a result of the determination in step S500, if decoding results for all codes are successes (S500, Yes), determination may be made for whether the calculated total number of corrected error bits is less than the predetermined threshold number of error bits (S600). If the total number of corrected error bits is less than the predetermined threshold number of error bits (S600, Yes), it may be determined that the state of the memory cells in which the data chunk DCK is stored is good, and the process may be ended. If the total number of corrected error bits is equal to or greater than the predetermined threshold number of error bits (S600, No), it may be determined that the state of the memory cells in which the data chunk DCK is stored is bad, and the corresponding data chunk DCK may be stored in other memory cells (S700). Namely, the data chunk DCK is moved to other memory cells of which state is good.

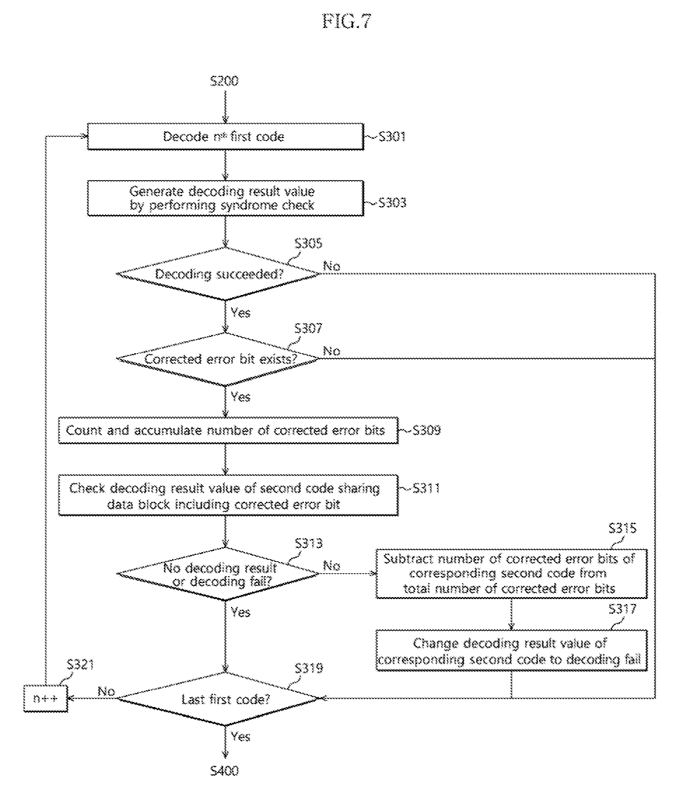

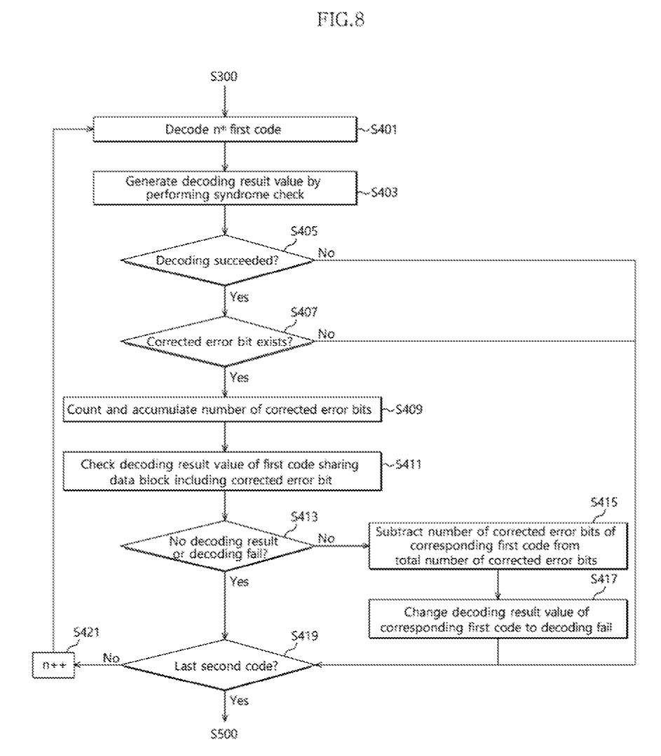

FIG. 7 is a flow chart illustrating the step S300 shown in FIG. 6 in more detail.

Referring to FIG. 7, the ECC unit 230 may decode an n^{th} row code (i.e., first code) of the data chunk DCK (S301). The decoding of the n^{th} row code may be performed based on an n^{th} row parity block. Here, n is 0 or a positive integer. Hereinbelow, as an example, it is assumed that a first row code R₁ is decoded.

The ECC unit 230 may perform the syndrome check for the decoded first row code R₁, and generate a decoding result value (S303). For example, the ECC unit 230 may perform the syndrome check for the decoded first row code R₁ and determine whether an error bit which is not corrected exists in the first row code R₁. If an error bit which is not corrected does not exist in the first row code R₁, the ECC unit 230 may generate a decoding result value (e.g., D=0, see FIG. 4A) indicating a decoding success. If an error bit which is not corrected exists in the first row code R₁, the ECC unit 230 may generate a decoding result value (e.g., D=1) indicating a decoding failure.

The ECC unit 230 may determine, based on the generated decoding result value, whether the decoding result of the decoded first row code R₁ is a success or a failure (S305). As a result of the determination of the step S305, if the decoding result is a failure (S305, No), the ECC unit 230 may determine whether the currently decoded row code is a last row code (S319). If the decoding result is a success (S305, Yes), the ECC unit 230 may determine whether a corrected error bit exists in the decoded first row code R₁ (S307).

As a result of the determination of the step S307, if a corrected error bit does not exist in the first row code R₁ (S307, No), the ECC unit 230 may perform the step S319. If a corrected error bit exists in the first row code R₁ (S307, Yes), the ECC unit 230 may count and accumulate the number of corrected error bits in the first row code R₁ (S309).

Thereafter, the ECC unit 230 may check the decoding result value of a column code (i.e., second code) which shares a data block where a corrected error bit is included (S311).

The ECC unit 230 may determine, based on the decoding result value of the checked column code, whether the decoding result value of the corresponding column code does not exist or the decoding result of the corresponding column code is a failure (S313). As a result of the determination of the step S313, if the decoding result of the corresponding column code is a success (S313, No), the ECC unit 230 may subtract the number of corrected error bits of the corresponding column code from the total number of corrected error bits (S315). In addition, the ECC unit 230 may change the decoding result value of the corresponding column code to a value indicating a decoding failure (S317). At this time, as aforementioned above, for offsetting double counting, a number equal to two times the number of corrected error bits of the corresponding column code may be subtracted from the total number of corrected error bits.

Also, as a result of the determination of the step S313, if the decoding result value of the column code which shares the data block where the corrected error bit is included in the first row code R₁ does not exist or the decoding result of the corresponding column code is a failure (S313, Yes), the ECC unit 230 may perform the step S319.

As a result of the determination of the step S319, if the currently decoded row code is a last row code (S319, Yes), the ECC unit 230 may perform the step S400. If the currently decoded row code is not a last row code (S319, No), the ECC unit 230 may select a next row code (e.g., the second row code R₂) (S321) and decode the selected second row code R₂ at the step S301. The steps S301 to S321 may be iteratively performed until decoding for all the row codes is completed.

FIG. 8 is a flow chart illustrating the step S400 shown in FIG. 6 in more detail.

Referring to FIG. 8, the ECC unit 230 may decode an n^{th} column code (i.e., second code) of the data chunk DCK (S401). The decoding of the n^{th} column code may be performed based on an n^{th} column parity block. Here, n is 0 or a positive integer. Hereinbelow, as an example, it is assumed that a first column code C₁ is decoded.

The ECC unit 230 may perform the syndrome check for the decoded first column code C₁, and generate a decoding result value (S403). For example, the ECC unit 230 may perform the syndrome check for the decoded first column code C₁, and determine whether an error bit which is not corrected exists in the first column code C₁. If an error bit does not exist in the first column code C₁, the ECC unit 230 may generate a decoding result value (e.g., D=0) indicating a decoding success. If an error bit exists, the ECC unit 230 may generate a decoding result value (e.g., D=1) indicating a decoding failure.

The ECC unit 230 may determine, based on the generated decoding result value, whether the decoding result of the decoded first column code C₁ is a success or a failure (S405). As a result of the determination of the step S405, if the decoding result is a failure (S405, No), the ECC unit 230 may determine whether the currently decoded column code is a last column code (S419). If the decoding result is a success (S405, Yes), the ECC unit 230 may determine whether a corrected error bit exists in the decoded first column code C₁ (S407).

As a result of the determination of the step S407, if a corrected error bit does not exist in the first column code C₁ (S407, No), the ECC unit 230 may perform the step S419 of determining whether the currently decoded column code is a last column code. If a corrected error bit exists in the first column code C₁ (S407, Yes), the ECC unit 230 may count and accumulate the number of corrected error bits in the first column code C₁ (S409). Thereafter, the ECC unit 230 may check the decoding result value of a row code (i.e., first code) which shares a data block where a corrected error bit is included (S411).

After checking, the ECC unit 230 may determine whether the decoding result value of the corresponding row code does not exist or the decoding result of the corresponding row code is a failure (S413). As a result of the determination of the step S413, if the decoding result of the row code which shares the data block where the corrected error bit is included is a success (S413, No), the ECC unit 230 may subtract the number of corrected error bits of the corresponding row code from the total number of corrected error bits (S415). In addition, the ECC unit 230 may change the decoding result value of the corresponding row code to a value indicating a decoding failure (S417).

Also, as a result of the determination of the step S413, if the decoding result value of the row code which shares the data block where the corrected error bit is included in the first column code C₁ does not exist or the decoding result of the corresponding row code is a failure (S413, No), the ECC unit 230 may perform the step S419 of determining whether the currently decoded column code is a last column code.

As a result of the determination of the step S419, if the currently decoded column code is a last column code (S419, Yes), the ECC unit 230 may perform the step S500 (see FIG. 6) of determining whether decoding results for all of the row codes and the column codes are successes. If the currently decoded column code is not a last column code (S419, No), the ECC unit 230 may select a next column code (e.g., the second column code C₂) (S421) and decode the selected second column code C₂ at the step S401. The steps S401 to S421 may be iteratively performed until decoding for all the column codes is completed.

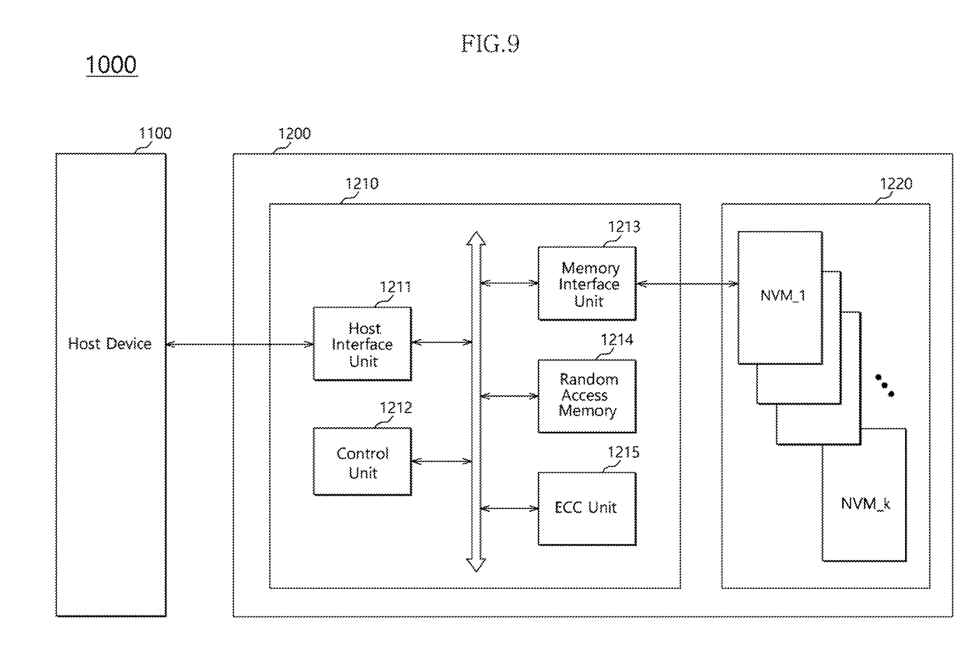

FIG. 9 is a block diagram illustrating a data processing system 1000 including a data storage device 1200 in accordance with an embodiment of the present invention.

Referring to FIG. 9, the data processing system 1000 may include a host device 1100 and the data storage device 1200.

The data storage device 1200 may include a controller 1210 and a nonvolatile memory device 1220. The data storage device 1200 may be used by being coupled to the host device 1100. The host device 1100 may be any suitable electronic device, such as, a mobile phone, an MP3 player, a laptop computer, a desktop computer, a game player, a television (TV), an in-vehicle infotainment system, and so forth. The data storage device 1200 is a memory system.

The controller 1210 may include a host interface unit 1211, a control unit 1212, a memory interface unit 1213, a random access memory 1214, and an error correction code (ECC) unit 1215 operatively linked via an internal bus. Any suitable internal bus may be used.

The random access memory 1214 may be used as the working memory of the control unit 1212. The random access memory 1214 may be used as a buffer memory which temporarily stores data read out from the nonvolatile memory device 1220 or data provided from the host device 1100. Any suitable random access memory may be used.

The control unit 1212 may control general operations of the controller 1210 in response to a request from the host device 1100. The control unit 1212 may drive a firmware or a software for controlling the nonvolatile memory device 1220. The control unit 1212 may be any suitable memory device controller.

The host interface unit 1211 may interface the host device 1100 and the controller 1210. For example, the host interface unit 1211 may communicate with the host device 1100 through one of various interface protocols such as a universal serial bus (USB) protocol, a universal flash storage (UFS) protocol, a multimedia card (MMC) protocol, a peripheral component interconnection (PCI) protocol, a PCI express (PCI-E) protocol, a parallel advanced technology attachment (PATA) protocol, a serial advanced technology attachment (SATA) protocol, a small computer system interface (SCSI) protocol, and a serial attached SCSI (SAS) protocol.

The memory interface unit 1213 may interface the controller 1210 and the nonvolatile memory device 1220. The memory interface unit 1213 may provide a command and an address to the nonvolatile memory device 1220. Furthermore, the memory interface unit 1213 may exchange data with the nonvolatile memory device 1220.

The ECC unit 1215 may ECC-encode data to be stored in the nonvolatile memory device 1220. Also, the ECC unit 1215 may ECC-decode data read out from the nonvolatile memory device 1220. Moreover, the ECC unit 1215 may count the number of error bits corrected in the process of ECC-decoding data, and calculate the total number of corrected error bits. The ECC unit 1215 may be included in the memory interface unit 1213.

The controller 1210 and the nonvolatile memory device 1220 may be manufactured as any one of various data storage devices. For example, the controller 1210 and the nonvolatile memory device 1220 may be integrated into one semiconductor device and may be manufactured as any one of a multimedia card in the form of an MMC, an eMMC, an RS-MMC and a micro-MMC, a secure digital card in the form of an SD, a mini-SD and an micro-SD, a universal serial bus (USB) storage device, a universal flash storage (UFS) device, a Personal Computer Memory Card International Association (PCMCIA) card, a compact flash (CF) card, a smart media card, a memory stick, and so forth.

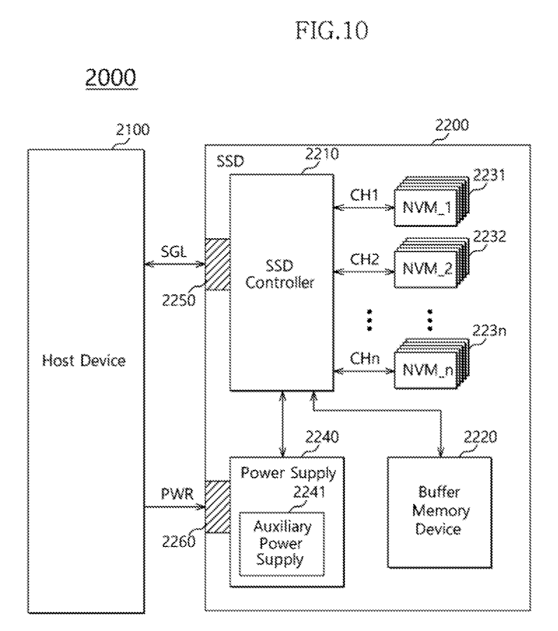

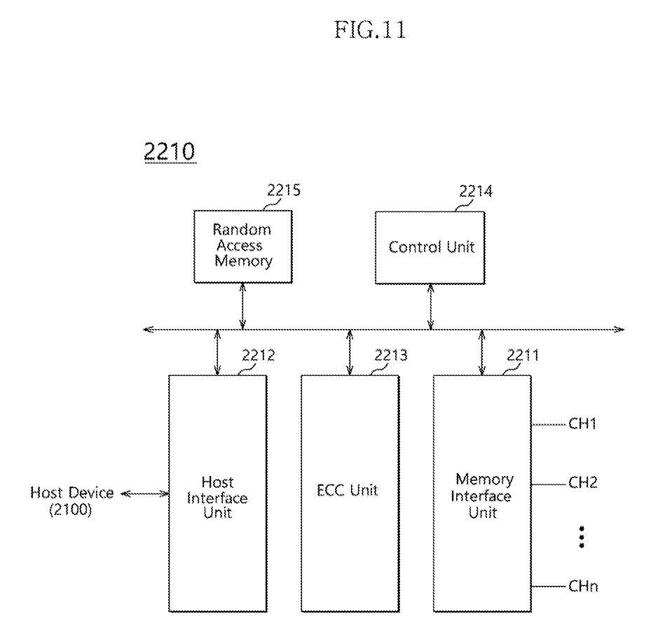

FIG. 10 is a block diagram illustrating a data processing system 2000 including a solid state drive (SSD) 2200 in accordance with an embodiment of the present invention.

Referring to FIG. 10, the data processing system 2000 may include a host device 2100 and the SSD 2200.

The SSD 2200 may include an SSD controller 2210, a buffer memory device 2220, nonvolatile memory (NVM) devices 2231 to 223n, a power supply 2240, a signal connector 2250, and a power connector 2260.

The SSD controller 2210 may access the nonvolatile memory devices 2231 to 223n in response to a request from the host device 2100.

The buffer memory device 2220 may temporarily store data to be stored in the nonvolatile memory devices 2231 to 223n. Further, the buffer memory device 2220 may temporarily store data read out from the nonvolatile memory devices 2231 to 223n. The data temporarily stored in the buffer memory device 2220 may be transmitted to the host device 2100 or the nonvolatile memory devices 2231 to 223n under control of the SSD controller 2210.

The nonvolatile memory devices 2231 to 223n may be used as storage media of the SSD 2200. The nonvolatile memory devices 2231 to 223n may be coupled with the SSD controller 2210 through a plurality of channels CH1 to CHn, respectively. One or more nonvolatile memory devices may be coupled to one channel. The nonvolatile memory devices coupled to each channel may be coupled to the same signal bus and data bus.

The power supply 2240 may provide power PWR inputted through the power connector 2260, to the inside of the SSD 2200. The power supply 2240 may include an auxiliary power supply 2241. The auxiliary power supply 2241 may supply power to allow the SSD 2200 to be normally terminated when a sudden power-off occurs. The auxiliary power supply 2241 may include large capacitance capacitors capable of charging power PWR.

The SSD controller 2210 may exchange a signal SGL with the host device 2100 through the signal connector 2250. The signal SGL may include a command, an address, data, and so forth. The signal connector 2250 may by configured by a connector such as of parallel advanced technology attachment (PATA), serial advanced technology attachment (SATA), small computer system interface (SCSI), serial attached SCSI (SAS), peripheral component interconnection (PCI) and PCI express (PCI-E) protocols, according to an interface scheme between the host device 2100 and the SSD 2200.

FIG. 11 is a block diagram illustrating the SSD controller 2210 of FIG. 10.

Referring to FIG. 11, the SSD controller 2210 may include a memory interface unit 2211, a host interface unit 2212, an error correction code (ECC) unit 2213, a control unit 2214, and a random access memory 2215.

The memory interface unit 2211 may provide control signals such as commands and addresses to the nonvolatile memory devices 2231 to 223n. Moreover, the memory interface unit 2211 may exchange data with the nonvolatile memory devices 2231 to 223n. The memory interface unit 2211 may distribute data transferred from the buffer memory device 2220 to the respective channels CH1 to CHn, under control of the control unit 2214. Furthermore, the memory interface unit 2211 may transfer data read out from the nonvolatile memory devices 2231 to 223n to the buffer memory device 2220, under control of the control unit 2214.

The host interface unit 2212 may provide interfacing with respect to the SSD 2200 in correspondence to the protocol of the host device 2100. For example, the host interface unit 2212 may communicate with the host device 2100 through any one of the parallel advanced technology attachment (PATA) protocol, the serial advanced technology attachment (SATA) protocol, the small computer system interface (SCSI) protocol, the serial attached SCSI (SAS) protocol, the peripheral component interconnection (PCI) protocol and the PCI express (PCI-E) protocol.

In addition, the host interface unit 2212 may perform a disk emulating function of supporting the host device 2100 to recognize the SSD 2200 as a hard disk drive (HDD).

The control unit 2214 may analyze and process the signal SGL inputted from the host device 2100. The control unit 2214 may control operations of the buffer memory device 2220 and the nonvolatile memory devices 2231 to 223n according to a firmware or a software for driving the SSD 2200.

The random access memory 2215 may be used as the working memory of the control unit 2214.

The control unit 2214 may analyze and process the signal SGL inputted from the host device 2100. The control unit 2214 may control operations of the buffer memory device 2220 and the nonvolatile memory devices 2231 to 223n according to a firmware or a software for driving the SSD 2200.

The ECC unit 2213 may generate parity data to be transmitted to the nonvolatile memory devices 2231 to 223n, among data stored in the buffer memory device 2220. The generated parity data may be stored, along with data, in the nonvolatile memory devices 2231 to 223n. The ECC unit 2213 may detect an error of the data read out from the nonvolatile memory devices 2231 to 223n. When the detected error is within a correction capability range, the ECC unit 2213 may correct the detected error. Moreover, the ECC unit 2213 may count the number of corrected error bits, and calculate the total number of corrected error bits.

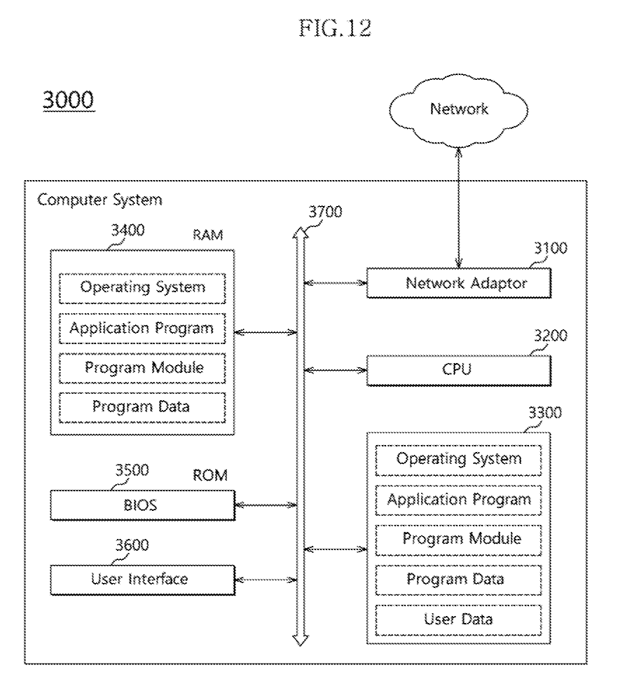

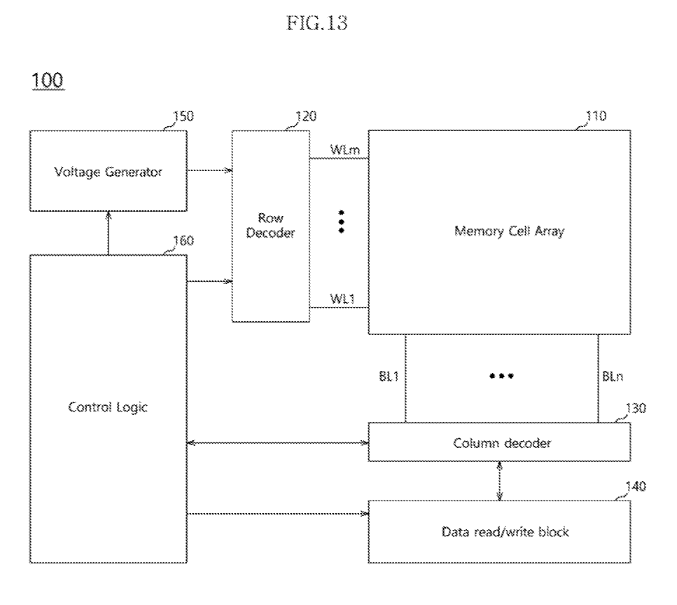

FIG. 12 is a block diagram illustrating a representation of an example of a computer system 3000 to which a data storage device 3300 in accordance with the embodiment is mounted.

Referring to FIG. 12, the computer system 3000 includes a network adaptor 3100, a central processing unit (CPU) 3200, the data storage device 3300, a random access memory (RAM) 3400, a read only memory (ROM) 3500 and a user interface 3600, which are electrically coupled to a system bus 3700. The data storage device 3300 may be configured by the data storage device 10 shown in FIG. 1, the data storage device 1200 shown in FIG. 9 or the SSD 2200 shown in FIG. 10.

The network adaptor 3100 may provide interfacing between the computer system 3000 and external networks. The central processing unit 3200 may perform general calculation processing for driving an operating system residing at the RAM 3400 or an application program.

The data storage device 3300 may store general data needed in the computer system 3000. For example, an operating system for driving the computer system 3000, an application program, various program modules, program data and user data may be stored in the data storage device 3300.

The RAM 3400 may be used as the working memory of the computer system 3000. Upon booting, the operating system, the application program, the various program modules and the program data needed for driving programs, which are read out from the data storage device 3300, may be loaded in the RAM 3400.

A basic input/output system (BIOS) which is activated before the operating system is driven may be stored in the ROM 3500. Information exchange between the computer system 3000 and a user may be implemented through the user interface 3600.

FIG. 13 is a block diagram illustrating a nonvolatile memory device 100 included in a data storage device in accordance with an embodiment of the present invention.

Referring to FIG. 13, the nonvolatile memory device 100 may include a memory cell array 110, a row decoder 120, a column decoder 130, a data read/write block 140, a voltage generator 150, and a control logic 160.

The memory cell array 110 may include memory cells which are arranged at areas where word lines WL1 to WLm and bit lines BL1 to BLn intersect with each other. The memory cells may be grouped by an access unit, such as a memory block as an erase unit and a page as a program and read unit.

The row decoder 120 may be coupled with the memory cell array 110 through the word lines WL1 to WLm. The row decoder 120 may operate according to control of the control logic 160. The row decoder 120 may decode an address provided from an external device (not shown). The row decoder 120 may select and drive the word lines WL1 to WLm, based on decoding results. For instance, the row decoder 120 may provide a word line voltage provided from the voltage generator 150, to the word lines WL1 to WLm.

The column decoder 130 may be coupled with the memory cell array 110 through the bit lines BL1 to BLn. The column decoder 130 may operate according to control of the control logic 160. The column decoder 130 may decode an address provided from the external device. The column decoder 130 may couple the bit lines BL1 to BLn with read/write circuits of the data read/write block 140 which respectively correspond to the bit lines BL1 to BLn, based on decoding results. Also, the column decoder 130 may drive the bit lines BL1 to BLn, based on the decoding results.

The data read/write block 140 may operate according to control of the control logic 160. The data read/write block 140 may operate as a write driver or a sense amplifier according to an operation mode. For example, the data read/write block 140 may operate as a write driver which stores data provided from the external device, in the memory cell array 110 in a write operation. For another example, the data read/write block 140 may operate as a sense amplifier which reads out data from the memory cell array 110 in a read operation.

The voltage generator 150 may generate voltages to be used in internal operations of the nonvolatile memory device 100. The voltages generated by the voltage generator 150 may be applied to the memory cells of the memory cell array 110. For example, a program voltage generated in a program operation may be applied to a word line of memory cells for which the program operation is to be performed. For another example, an erase voltage generated in an erase operation may be applied to a well area of memory cells for which the erase operation is to be performed. For still another example, a read voltage generated in a read operation may be applied to a word line of memory cells for which the read operation is to be performed.

The control logic 160 may control general operations of the nonvolatile memory device 100, based on control signals provided from the external device. For example, the control logic 160 may control main operations of the nonvolatile memory device 100 such as read, write and erase operations of the nonvolatile memory device 100.

While various embodiments have been described above, it will be understood to those skilled in the art that the embodiments described are examples only. Accordingly, the data storage device and the operating method thereof described herein should not be limited based on the described embodiments.

What is claimed is:

1. A method for operating a data storage device, the method comprising:
reading out a data chunk from a nonvolatile memory device;
arranging first codes and second codes of the read-out data chunk in the form of a matrix; and
determining the total number of corrected error bits for the data chunk by decoding the respective first codes and the respective second codes, and summing the numbers of corrected error bits of the respective decoded first codes and the respective decoded second codes.

2. The method according to claim 1, wherein the determining of the total number of corrected error bits further comprises:
a first step of decoding sequentially the first codes, and summing the numbers of corrected error bits of the respective decoded first codes; and
a second step of decoding sequentially the second codes, counting the numbers of corrected error bits of the respective decoded second codes, and summing the numbers of corrected error bits of the respective decoded second codes with the numbers of corrected error bits of the respective decoded first codes.

3. The method according to claim 2, wherein the first step further comprises:
decoding at least one first code among the first codes;
counting and accumulating the number of corrected error bits of the decoded first code; and
repeating the decoding and the counting and accumulating for a next first code until the decoded first code is a last first code among the first codes.

4. The method according to claim 3, further comprising:
after the decoding of the first code, performing a syndrome check for the decoded first code, and generating a decoding result value indicating a decoding success or a decoding failure for the first code.

5. The method according to claim 3, further comprising:
checking a decoding result value of a second code which shares a data block where a corrected error bit of the decoded first code is included;
determining whether a decoding result of the second code is a success based on the decoding result value of the second code; and
subtracting the number of corrected error bits of the second code from the total number of corrected error bits, when the decoding result of the second code is a success.

6. The method according to claim 5, further comprising:
changing the decoding result value of the second code to a value indicating a decoding failure.

7. The method according to claim 3, further comprising:
starting decoding for the second codes, when the ECC-decoded first code is the last first code.

8. The method according to claim 2, wherein the second step comprises:
decoding at least one second code among the second codes;
counting and accumulating the number of corrected error bits of the decoded second code; and
repeating the decoding and the counting and accumulating for a next second code until the decoded second code is a last second code among the second codes.

9. The method according to claim 8, further comprising:
after the decoding of the second code, performing a syndrome check for the decoded second code, and generating a decoding result value indicating a decoding success or a decoding failure for the second code.

10. The method according to claim 8, further comprising:
checking a decoding result value of a first code which shares a data block where a corrected error bit of the decoded second code is included;
determining whether a decoding result of the first code is a success based on the decoding result value of the first code; and
subtracting the number of corrected error bits of the first code from the total number of corrected error bits, when the decoding result of the first code is a success.

11. The method according to claim 10, further comprising:
changing the decoding result value of the first code to a value indicating a decoding failure.

12. The method according to claim 8, further comprising:
determining whether decoding results of the respective decoded first codes and the respective decoded second codes are successes, when the decoded second code is a last second code among the second codes; and
completing a decoding operation for the data chunk when the decoding results of the respective decoded first codes and, the respective decoded second codes are successes, and restarting decoding of the first codes when at least one of the decoding results of the respective decoded first codes and the respective decoded second codes is a failure.

13. A data storage device comprising:
a nonvolatile memory device in which a data chunk is stored;
a control unit suitable for reading out the data chunk from the nonvolatile memory device; and
an error correction code (ECC) unit suitable for:
arranging first codes and second codes of the read-out data chunk in the form of a matrix, and
determining the total number of corrected error bits for the data chunk by performing a decoding operation for the respective first codes and the respective second codes, and counting and summing the numbers of corrected error bits of the respective decoded first codes and the respective decoded second codes.

14. The data storage device according to claim 13, wherein the ECC unit performs a syndrome check for the respective decoded first codes and the respective decoded second codes, and generates decoding result values indicating decoding successes or decoding failures for the respective decoded first codes and the respective decoded second codes.

15. The data storage device according to claim 14, wherein the ECC unit checks a decoding result value for a decoded second code which shares a data block where a corrected error bit of a decoded first code is included, determines whether a decoding result of the decoded second code is a success, and, subtracts the number of corrected error bits of the decoded second code from the total number of corrected error hits when the decoding result of the decoded second code is a success.

16. The data storage device according to claim 15, wherein the ECC unit changes the decoding result value for the decoded second code to a value indicating a decoding failure.

17. The data storage device according to claim 14, wherein the ECC unit checks a decoding result value for a decoded first code which shares a data block where a corrected error bit of a decoded second code is included, determines whether a decoding result of the decoded first code is a success, and subtracts the number of corrected error bits of the decoded first code from the total number of corrected error bits when the decoding result of the decoded first code is a success.

18. The data storage device according to claim 17, wherein the ECC unit changes the decoding result value for the decoded first code to a value indicating a decoding failure.

19. The data storage device according to claim 13, wherein the ECC unit performs the decoding operation sequentially for the first codes, and then performs the decoding operation sequentially for the second codes.

20. The data storage device according to claim 19, wherein the ECC unit determines whether decoding results of the respective decoded first codes and the respective decoded second codes are successes when decoding for the second codes is completed, completes the decoding operation for the data chunk when all the decoding results of the respective decoded first codes and the respective decoded second codes are successes, and restarts decoding for the first codes when at least one of the decoding results of the respective decoded first codes and the respective decoded second codes is a failure.
